(19) United States
(12) Patent Application Publication
(10) Pub. No.: US 2025/0280692 A1
(43) Pub. Date: Sep. 4, 2025

(54) PIXEL STRUCTURE AND DISPLAY PANEL

(71) Applicant: HKC CORPORATION LIMITED, SHENZHEN (CN)

(72) Inventors: Zhi YANG, SHENZHEN (CN); Yangling TANG, SHENZHEN (CN); Zhisheng XIE, SHENZHEN (CN); Chenchen JIANG, SHENZHEN (CN); Qin LIANG, SHENZHEN (CN); Xiufeng ZHOU, SHENZHEN (CN); Haijiang YUAN, SHENZHEN (CN)

(73) Assignee: HKC CORPORATION LIMITED, SHENZHEN (CN)

(21) Appl. No.: 19/030,403

(22) Filed: Jan. 17, 2025

(30) Foreign Application Priority Data
Feb. 29, 2024 (CN) 202410235506.4

(51) Int. Cl. H10K 59/35; H10K 59/122; H10K 59/80

(52) U.S. Cl. CPC H10K 59/353; H10K 59/122; H10K 59/352; H10K 59/8052

(57) ABSTRACT

A pixel structure and a display panel are provided. The pixel structure includes a first sub-pixel, a second sub-pixel and a third sub-pixel. The first sub-pixel and the second sub-pixel are alternately disposed along a first direction and form a first pixel row. The third sub-pixels are disposed along the first direction and form a second pixel row. The first pixel row and the second pixel row are alternately disposed along a second direction. Centers of two first sub-pixels and two second sub-pixels from adjacent two rows and adjacent two columns may be connected to form a virtual quadrilateral. The third sub-pixel is located within the virtual quadrilateral. The pixel structure further includes spacer structures. Each spacer structure is configured to enclose one sub-pixel. The spacer structure is configured to electrically connect the cathodes of the sub-pixels to each other.

### CROSS REFERENCE TO RELATED APPLICATIONS

This application claims priority to Chinese Patent Application No. 202410235506.4, filed Feb. 29, 2024, which is herein incorporated by reference in its entirety.

### TECHNICAL FIELD

The present disclosure relates to the field of display technologies, and in particular to a pixel structure and a display panel.

### BACKGROUND

Nowadays, in conventional manufacturing methods of organic light-emitting diodes (OLEDs), the material vaporization regions are defined by fine metal mask (FMM). However, due to issues such as common color mixing, product designers must ensure generally too large PDL gap values or pixel pitches, which may result in reduction of product apertures. The product lifespan capacity may be directly affected.

### SUMMARY OF THE DISCLOSURE

A first technical scheme adopted by the present disclosure is to provide a pixel structure. The pixel structure includes a first sub-pixel, a second sub-pixel and a third sub-pixel. The colors of the first sub-pixel, the second sub-pixel and the third sub-pixel are different from each other. The first sub-pixel and the second sub-pixel are alternately disposed along a first direction and form a first pixel row. A plurality of the third sub-pixels are disposed along the first direction and form a second pixel row. The first pixel row and the second pixel row are alternately disposed along a second direction, and the first direction and the second direction are perpendicular to each other. Two first sub-pixels and two second sub-pixels from adjacent two rows and adjacent two columns are arranged in a 2×2 matrix, the two first sub-pixels are located in different rows and different columns, the two second sub-pixels are located in different rows and different columns. Two centers of the two first sub-pixels and the two centers of the two second sub-pixels are capable of being connected to form a virtual quadrilateral. The third sub-pixel is located within the virtual quadrilateral. A side of the third sub-pixel is parallel to a proximate side of an adjacent sub-pixels. The pixel structure further includes spacer structures. The spacer structures are configured to enclose the sub-pixels, and are in one-to-one correspondence with the sub-pixels. The spacer structure is configured to electrically connect the cathodes of the sub-pixels to each other.

In some embodiments, each of the first sub-pixel and the second sub-pixel is a rhombus, the third sub-pixel is a parallelogram. A diagonal line of the rhombus is configured to extend in the first direction, another diagonal line of the rhombus is configured to extend in the second direction. The first sub-pixel and the second sub-pixel adjacent to each other along the first direction are configured to be disposed as corner-facing-corner, and the first sub-pixel and the second sub-pixel adjacent to each other along the second direction are configured to be disposed as corner-facing-corner. A side of the spacer structure is parallel to a proximate side of a sub-pixel adjacent to the spacer structure. The first sub-pixel and the third sub-pixel adjacent to the first sub-pixel share a side wall of the spacer structure, and the second sub-pixel and the third sub-pixel adjacent to the second sub-pixel share a side wall of the spacer structure.

In some embodiments, the region enclosed by the spacer structure is polygonal. The corners of the region enclosed by the spacer structure configured to enclose the first sub-pixel are flat chamfers or rounded chamfers, and the corners of the region enclosed by the spacer structure configured to enclose the second sub-pixel are flat chamfers or rounded chamfers.

In some embodiments, the spacer structure includes a spacer part and an eave structure. The eave structure is provided on an upper surface of the spacer part. The eave structure is configured to cover the spacer part, and extend beyond the spacer part in a direction parallel to the spacer part. The cross-section of the spacer structure along a plane parallel to the eave structure is configured to taper along a direction toward the eave structure.

In some embodiments, for each spacer structure, at least a part of the side wall is a first side wall. The spacer part of the first side wall is electrically conductive, and is configured to contact the cathode of the sub-pixel adjacent to the first side wall, and achieve an electrical connection between the spacer structure and the sub-pixel. The cathode of the sub-pixel is vaporized onto a surface of the light-emitting layer of the sub-pixel by a vaporization source. The first direction is a long-edge direction of the vaporization source, and the second direction is a scanning direction of the vaporization source.

In some embodiments, a part of the side walls of each spacer structure is the first side wall, and another part of the side walls of the each spacer structure is a second side wall. The spacer part of the second side wall is insulating.

In some embodiments, the spacer structure configured to enclose the first sub-pixel is referred to as a first spacer structure, and the spacer structure configured to enclose the second sub-pixel is referred to as a second spacer structure. A straight line on which the diagonal line of the rhombus extending in the first direction is referred to as a first symmetry line, and a straight line on which the diagonal line of the rhombus extending in the second direction is referred to as a second symmetry line. For the first spacer structure and the second spacer structure adjacent to each other along the first direction, the first side wall of the first spacer structure and the first side wall of the second spacer structure are disposed at opposite sides of the corresponding first symmetry line, the first side walls adjacent to each other along the first direction are configured to contact each other and are electrically connected. For the first spacer structure and the second spacer structure adjacent to each other along the second direction: the first side wall of the first spacer structure and the first side wall of the second spacer structure are disposed at the same side of the respectively corresponding first symmetry lines; or the first side wall of the first spacer structure and the first side wall of the second spacer structure are disposed at opposite sides of the respectively corresponding first symmetry lines.

In some embodiments, the spacer structure configured to enclose the first sub-pixel is referred to as a first spacer structure, and the spacer structure configured to enclose the second sub-pixel is referred to as a second spacer structure. A straight line on which the diagonal line of the rhombus extending in the first direction is referred to as a first symmetry line, and a straight line on which the diagonal line of the rhombus extending in the second direction is referred to as a second symmetry line. For the first spacer structure and the second spacer structure adjacent to each other along the second direction, the first side wall of the first spacer structure and the first side wall of the second spacer structure are disposed at opposite sides of the corresponding second symmetry line; the first side walls adjacent to each other along the second direction are configured to contact each other and are electrically connected. For the first spacer structure and the second spacer structure adjacent to each other along the first direction: the first side wall of the first spacer structure and the first side wall of the second spacer structure are disposed at the same side of the respectively corresponding second symmetry lines; or the first side wall of the first spacer structure and the first side wall of the second spacer structure are disposed at opposite sides of the respectively corresponding second symmetry lines.

In some embodiments, the side walls of a part of the first spacer structures are all first side walls; and/or, the side walls of a part of the second spacer structures are all first side walls.

A second technical solution adopted by the present disclosure is to provide a display panel. The display panel includes the pixel structure. The pixel structure includes a first sub-pixel, a second sub-pixel and a third sub-pixel. The colors of the first sub-pixel, the second sub-pixel and the third sub-pixel are different from each other. The first sub-pixel and the second sub-pixel are alternately disposed along a first direction and form a first pixel row. A plurality of the third sub-pixels are disposed along the first direction and form a second pixel row. The first pixel row and the second pixel row are alternately disposed along a second direction, and the first direction and the second direction are perpendicular to each other. Two first sub-pixels and two second sub-pixels from adjacent two rows and adjacent two columns are arranged in a 2×2 matrix, the two first sub-pixels are located in different rows and different columns, the two second sub-pixels are located in different rows and different columns. Two centers of the two first sub-pixels and the two centers of the two second sub-pixels are capable of being connected to form a virtual quadrilateral. The third sub-pixel is located within the virtual quadrilateral. A side of the third sub-pixel is parallel to a proximate side of an adjacent sub-pixels. The pixel structure further includes spacer structures. The spacer structures are configured to enclose the sub-pixels, and are in one-to-one correspondence with the sub-pixels. The spacer structure is configured to electrically connect the cathodes of the sub-pixels to each other.

### BRIEF DESCRIPTION OF THE DRAWINGS

To more clearly illustrate technical solutions in the present disclosure, the drawings required in the description of the embodiments will be briefly introduced below. Obviously, the drawings in the following description are only some embodiments of the present disclosure. For those of ordinary skills in the art, other drawings could be obtained based on these drawings without creative efforts.

FIG. 1 is a schematic structural diagram of a pixel structure according to a first embodiment of the present disclosure.

FIG. 2 is a schematic sectional structural diagram along a direction E-E of FIG. 1.

FIG. 3 is a schematic structural diagram of a pixel structure according to a second embodiment of the present disclosure.

FIG. 4 is a schematic structural diagram of a pixel structure according to a third embodiment of the present disclosure.

FIG. 5 is a schematic structural diagram of a pixel structure according to a fourth embodiment of the present disclosure.

FIG. 6 is a schematic structural diagram of a pixel structure according to a fifth embodiment of the present disclosure.

FIG. 7 is a schematic structural diagram of a pixel structure according to a sixth embodiment of the present disclosure.

FIG. 8 is a schematic structural diagram of a pixel structure according to a seventh embodiment of the present disclosure.

FIG. 9 is a schematic structural diagram of a pixel structure according to an eighth embodiment of the present disclosure.

FIG. 10 is a schematic structural diagram of a pixel structure according to a ninth embodiment of the present disclosure.

FIG. 11 is a schematic structural diagram of a pixel structure according to a tenth embodiment of the present disclosure.

FIG. 12 is a schematic structural diagram of a pixel structure according to an eleventh embodiment of the present disclosure.

FIG. 13 is a schematic structural diagram of a pixel structure according to a twelfth embodiment of the present disclosure.

FIG. 14 is a schematic structural diagram of a pixel structure according to a thirteenth embodiment of the present disclosure.

FIG. 15 is a schematic comparison diagram of a sub-pixel life decay process according to an embodiment of the present disclosure.

### REFERENCE NUMBER

10, sub-pixel; 11, anode; 12, light-emitting layer; 13, cathode; 10A, first sub-pixel; 10B, second sub-pixel; 10C, third sub-pixel; 110, first pixel row; 120, second pixel row; X, first direction; Y, second direction; D1, first symmetry line; D2, second symmetry line; G1, first side; G2, second side; G3, third side; G4, fourth side; 20, spacer structure; 21, side wall; 21A, first side wall; 21B, second side wall; 211, spacer part; 212, eave structure; 30, pixel definition layer; 31, pixel aperture.

### DETAILED DESCRIPTION

Technical solutions of embodiments of the present disclosure are described in detail below in conjunction with the accompanying drawings.

In the following description, specific details such as particular system structures, interfaces, techniques, etc. are presented for the purpose of illustration and not for the purpose of limitation, to facilitate a thorough understanding of the present disclosure.

The technical solutions in embodiments of the present disclosure will be described clearly and thoroughly in connection with accompanying drawings of the embodiments of the present disclosure. Obviously, the described embodiments are only a part of the embodiments, but not all of them. All other embodiments obtained by a person of ordinary skills in the art based on embodiments of the present disclosure without creative efforts should all be within the protection scope of the present disclosure.

The terms ‘first’, ‘second’, and ‘third’ in this disclosure are only for the purpose of description, and cannot be construed as indicating or implying relative importance or implicitly indicating the number of technical features referred to. Therefore, the features defined with ‘first’, ‘second’, and ‘third’ may explicitly or implicitly include at least one of the features. In the description of the present disclosure, ‘a plurality of’ means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as illustrated in the drawings). If the specific posture changes, then the directional indication will change accordingly. In addition, the terms ‘include’, ‘comprise’ and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to ‘embodiment’ herein means that, a specific feature, structure, or characteristic described in conjunction with the embodiments may be included in at least one embodiment of the present disclosure. The appearance of this phrase in various locations of the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

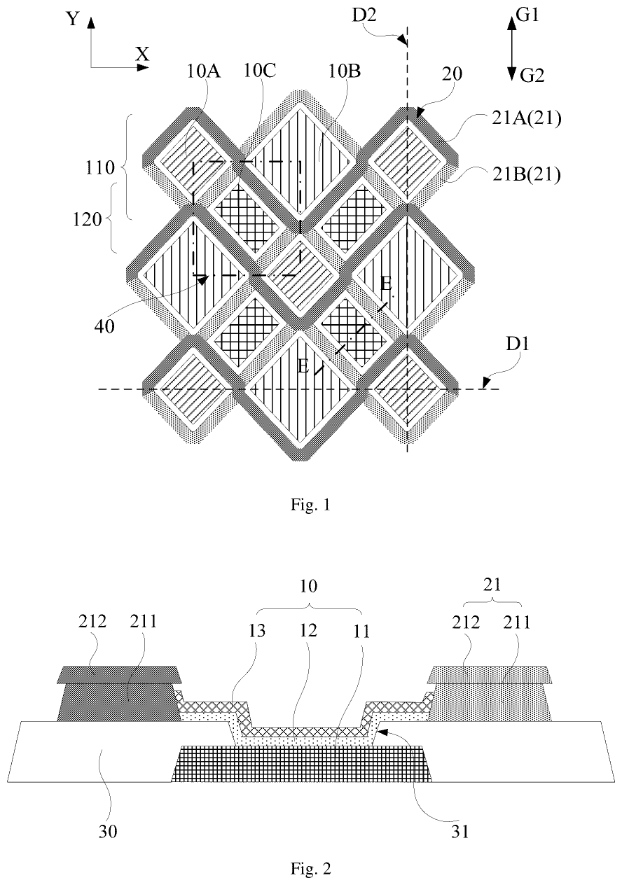

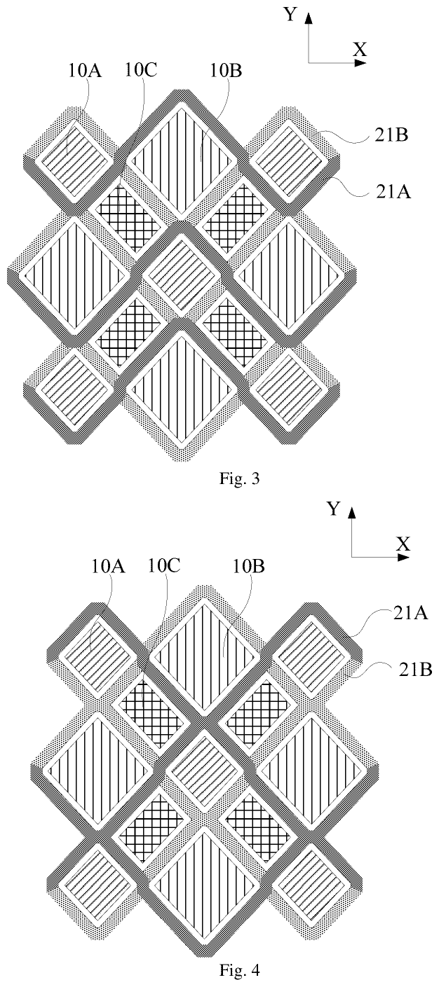

As illustrated in FIG. 1 and FIG. 2, FIG. 1 is a schematic structural diagram of a pixel structure according a first embodiment of the present disclosure, and FIG. 2 is a schematic sectional structural diagram along a direction E-E of FIG. 1.

A pixel structure is provided in the present disclosure. The pixel structure includes a first sub-pixel 10A, a second sub-pixel 10B and a third sub-pixel 10C. The colors of the first sub-pixel 10A, the second sub-pixel 10B and the third sub-pixel 10C are different from each other. The first sub-pixel 10A and the second sub-pixel 10B are alternately disposed along a first direction X and form a first pixel row 110. A plurality of third sub-pixels 10C are disposed along the first direction X and form the second pixel row 120. The first pixel row 110 and the second pixel row 120 are alternately disposed along a second direction Y. The first direction X is perpendicular to the second direction Y. Two first sub-pixels 10A and two second sub-pixels 10B from two adjacent rows and two adjacent columns are arranged in a 2×2 matrix. The two first sub-pixels 10A are located in different rows and in different columns, and the two second sub-pixels 10B are located in different rows and in different columns. Two centers of the two first sub-pixels 10A and two centers of the two second sub-pixels 10B are capable of being connected as four vertices to form a virtual quadrilateral. The third sub-pixel 10C is located within this virtual quadrilateral. A side of the third sub-pixel 10C is parallel to a proximate side of a sub-pixel 10 adjacent to the third sub-pixel 10C. The pixel structure further includes a spacer structure 20. The spacer structures 20 are each configured to enclose the sub-pixel 10, and are in one-to-one correspondence with the sub-pixels 10. The spacer structure 20 is configured to electrically connect cathodes 13 of the sub-pixels 10 to each other.

In the present disclosure, the spacer structure 20 is configured to enclose the sub-pixel 10. In this way, the spacer structure 20 may isolate different sub-pixels 10 and prevent pixel crosstalk. The spacer structure 20 may also enable mutual electrical connection between the cathodes 13 of the sub-pixels 10, thereby facilitating the electrical interconnection of the cathodes 13 of the sub-pixels 10 of a whole panel. In addition, a fine metal mask is adopted in the related technology to define a material vaporization region. In contrast, the spacer structure 20 in the present disclosure may further reduce a spacing between the sub-pixels 10, effectively increase an area of the pixel aperture 31, and reduce current density of the pixels. In this way, a product lifespan may be effectively increased, and production cost of the pixel structure may also be reduced.

A pixel definition layer 30 is also provided in the present disclosure. The pixel definition layer 30 defines a location for the sub-pixel 10. Specifically, a plurality of pixel apertures 31 are defined in the pixel definition layer 30. The sub-pixel 10 is disposed within the pixel aperture 31. The pixel apertures 31 are disposed in one-to-one correspondence with the sub-pixels 10.

The material and thickness of the pixel definition layer 30 are not limited herein, and may be selected per actual requirements.

In the present disclosure, the first sub-pixel 10A, the second sub-pixel 10B and the third sub-pixel 10C represents sub-pixels 10 of different colors.

The sub-pixel 10 includes an anode 11, a light-emitting layer 12, and a cathode 13 cascading disposed or stacked in sequence. The materials of the anode 11, the light-emitting layer 12, and the cathode 13 are not limited herein, and may be selected per actual requirements. The cathode 13 of the sub-pixel 10 is vaporized onto a surface of the light-emitting layer 12 of the sub-pixel 10 by a vaporization source. The first direction X is a long-edge direction of the vaporization source, and the second direction Y is a scanning direction of the vaporization source.

The sub-pixel 10 includes an OLED.

In some embodiments, the first sub-pixel 10A is a red sub-pixel 10. The second sub-pixel 10B is a blue sub-pixel 10. The third sub-pixel 10C is a green sub-pixel 10.

In some other embodiments, the first sub-pixel 10A, the second sub-pixel 10B, and the third sub-pixel 10C may respectively represent sub-pixels 10 of other colors. The colors of the sub-pixels are not limited herein and may be selected per actual requirements. In the present disclosure, the 10 relationships among sizes of the light-emitting areas of the sub-pixels 10 of various colors are not limited herein, and may be selected per actual requirements.

A spacing between the third sub-pixel 10C and the second sub-pixel 10B may be greater than, equal to, or less than a spacing between the third sub-pixel 10C and the first sub-pixel 10A, which may be determined per actual requirements.

In some embodiments, the spacing between the third sub-pixel 10C and the second sub-pixel 10B is equal to the spacing between the third sub-pixel 10C and the first sub-pixel 10A, which would guarantee a display homogeneity.

The first direction X is a row direction of the sub-pixel 10. The second direction Y is a column direction of the sub-pixel 10.

For two first pixel rows 110 adjacent to each other along the second direction Y, an alternating order in the first direction X between the first sub-pixel 10A and the second sub-pixel 10B of one of the two first pixel rows 110 is opposite to an alternating order in the first direction X between the first sub-pixel 10A and the second sub-pixel 10B of another one of the two first pixel row 110. In some embodiments, for two adjacent first pixel rows 110: in one first pixel row 110, the first sub-pixel 10A and the second sub-pixel 10B are alternately arranged in sequence along the first direction X; and in another first pixel row 110, the second sub-pixel 10B and the first sub-pixel 10A are alternately arranged in sequence along the first direction X.

A side of the third sub-pixel 10C is parallel to a proximate side of the sub-pixel 10 adjacent to the third sub-pixel 10C. In other words, a side edge of the third sub-pixel 10C proximate to an adjacent sub-pixel 10 is parallel to a side edge of this adjacent sub-pixel 10 proximate to the third sub-pixel 10C. Specifically, the side of the third sub-pixel 10C and a proximate side of the adjacent first sub-pixel 10A are in parallel with each other, the side of the third sub-pixel 10C and a proximate side of the adjacent second sub-pixel 10B are in parallel with each other.

In some embodiments, each of the first sub-pixel 10A and the second sub-pixel 10B is a rhombus. The third sub-pixel 10C is a parallelogram. One diagonal line of the rhombus is configured to extend in the first direction X, another diagonal line of the rhombus is configured to extend in the second direction Y. The first sub-pixel 10A and the second sub-pixel 10B adjacent to each other in the first direction X are disposed to be corner-facing-corner. The term “corner-facing-corner” means that a corner of a sub-pixel 10 is facing or against a corner of another sub-pixel 10. The first sub-pixel 10A and the second sub-pixel 10B adjacent to each other in the second direction Y are disposed as corner-facing-corner. In other words, in each first pixel row 110, a diagonal line of the first sub-pixel 10A extending along the first direction X and a diagonal line of the second sub-pixel 10B extending along the first direction X are on a same straight line, such that the first sub-pixel 10A and the second sub-pixel 10B are disposed as corner-facing-corner in the first direction X. Similarly, for the first sub-pixel 10A and the second sub-pixel 10B that are adjacent to each other in the second direction Y, a diagonal line of the first sub-pixel 10A extending along the second direction Y and the diagonal line of the second sub-pixel 10B extending along the second direction Y are one a same straight line, such that the first sub-pixel 10A and the second sub-pixel 10B are disposed as corner-facing-corner in the second direction Y.

In some embodiments, provided that the side of the third sub-pixel 10C is parallel to the proximate side of the adjacent sub-pixel 10, the third sub-pixel 10C may also be other kind of polygons, such as a hexagon.

In the present disclosure, there is a gap between the first sub-pixel 10A and the second sub-pixel 10B adjacent to each other along the first direction X or the second direction Y.

In some embodiments, the extension direction of each of the side edges of all the sub-pixels 10 is configured to intersect with both the first direction X and the second direction Y. That is, the extension direction of any of the side edges of the sub-pixel 10 is neither parallel to the first direction X nor parallel to the second direction Y.

The spacer structure 20 is a ring-shaped structure, and is configured to protrude from the pixel definition layer 30. The spacer structure 20 is configured to enclose the pixel aperture 31, so as to enclose the sub-pixels 10. A single spacer structure 20 encloses a single pixel aperture 31.

Further, the spacer structure 20 is parallel to a proximate side of an adjacent sub-pixel 10. In other words, the side edge of the spacer structure 20 proximate to the adjacent sub-pixel 10 and the side edge of the adjacent sub-pixel 10 proximate to the spacer structure 20 are parallel to each other, thereby facilitating a regular preparation of the spacer structure 20.

The first sub-pixel 10A and an adjacent third sub-pixel 10C share a side wall 21 of the spacer structure 20. The second sub-pixel 10B and the adjacent third sub-pixel 10C share another side wall 21 of the spacer structure 20. In other words, the spacer structure 20 enclosing the first sub-pixel 10A shares a same side wall 21 with the spacer structure 20 enclosing the third sub-pixel 10C adjacent to this first sub-pixel 10A, thereby reducing the spacing between the sub-pixels 10 and beneficially increasing the pixel aperture ratio.

The region enclosed by the spacer structure 20 is polygonal. The corners of the region enclosed by the spacer structure 20 configured to enclose the first sub-pixel 10A are flat chamfers or rounded chamfers. The corners of the region enclosed by the spacer structure 20 configured to enclose the second sub-pixel 10B are flat chamfers or rounded chamfers. In the present disclosure, by removing sharp corners of the spacer structures 20 for enclosing the first sub-pixel 10A and the second sub-pixel 10B, the effect of the irregularity of the sharp corners on the area size of the pixel aperture 31 may be eliminated, thereby facilitating the reduction of the spacing between the first sub-pixel 10A and the second sub-pixel 10B, and further increasing the pixel aperture ratio. Furthermore, by this way, the problem of poor attachment between the spacer structure 20 and the sub-pixel 10 may also be avoided. The cathode 13 of the sub-pixel 10 at a sharp corner is prone to a problem of poor attachment with the spacer structure 20.

In some embodiments, the corners of the region enclosed by the spacer structure 20 configured to enclose the first sub-pixel 10A are flat chamfers. The corners of the region enclosed by the spacer structure 20 configured to enclose the second sub-pixel 10B are flat chamfers.

In some embodiments, the corners of the region enclosed by the spacer structure 20 configured to enclose the third sub-pixel 10C are flat chamfers or rounded chamfers, which is not unnecessarily limited herein. The specific arrangement of the corners may be selected per actual requirements.

The spacer structure 20 includes a spacer part 211 and an eave structure 212. The eave structure 212 is provided on an upper surface of the spacer part 211. The eave structure 212 is configured to cover or shield the spacer part 211, and extends beyond the spacer part 211 in a direction parallel to the spacer part 211. In other words, an orthographic projection of the eave structure 212 onto the pixel definition layer 30 overlaps or covers the orthographic projection of the spacer part 211 onto the pixel definition layer 30, and an area of the orthographic projection of the eave structure 212 onto the pixel definition layer 30 is greater than that of the orthographic projection of the spacer part 211 onto the pixel definition layer 30. During the vaporization process of the sub-pixel 10, a vaporization angle of the vaporized material may be adjusted by edges of the eave structure 212, so that the cathode 13 may cover the light-emitting layer 12 and achieve a good attachment between the cathode 13 and the spacer structure 20.

The spacer part 211 of the spacer structure 20 is attached to the cathode 13 of the enclosed sub-pixel 10.

A cross-section of the spacer structure 20 along a plane parallel to the eave structure 212 is configured to taper along a direction toward the eave structure 212. In other words, an angle between a side face of the spacer part 211 and a portion of the eave structure 212 extending beyond the spacer part 211 is less than 90 degrees. In this way, an attachment effect of the cathode 13 of the sub-pixel 10 to the side face of the spacer part 211 may be enhanced, and thereby facilitating a sound attachment of the cathode 13 of the sub-pixel 10 to the spacer part 211.

For each spacer structure 20, at least a portion of the side wall 21 is a first side wall 21A. The spacer part 211 of the first side wall 21A is electrically conductive, and configured to contact the cathode 13 of an adjacent sub-pixel 10, so as to achieve an electrical connection between the spacer structure 20 and the sub-pixel 10. In other words, each spacer structure 20 includes a plurality of side walls 21. Each side wall 21 corresponds to a side edge of the enclosed sub-pixel 10. A part of or all the side walls 21 in each spacer structure 20 are the first side wall 21A. The spacer part 211 of the first side wall 21A of the spacer structure 20 is attached to the cathode 13 of the adjacent sub-pixel 10, so as to achieve the electrical connection between this spacer structure 20 and the corresponding sub-pixel 10.

In the present disclosure, the first direction X is configured as the long-edge direction of the vaporization source, and the second direction Y is configured as the scanning direction of the vaporization source. In this way, any first side wall 21A of the spacer structure 20 is enabled to attach with the cathode 13 of the sub-pixel 10, thereby achieving the electrical connection between the spacer structure 20 and the adjacent sub-pixel 10.

In some embodiments, a part of the side wall 21 of each spacer structure 20 is the first side wall 21A and another part of the side wall 21 of each spacer structure 20 is a second side wall 21B. The spacer part 211 of the second side wall 21B is insulating. The eave structure 212 is insulating.

The wall thickness value of the first side wall 21A and the wall thickness value of the second side wall 21B are not limited herein, and may be selected per actual requirements. The wall thickness of the first side wall 21A may be greater than or equal to, or less than, the wall thickness of the second side wall 21B.

The material of the spacer part 211 of the second side wall 21B may be the same as or different from that of the eave structure 212. These materials are not unnecessarily limited herein and may be selected per actual requirements.

In some embodiments, the spacer structure 20 configured to enclose the first sub-pixel 10A is defined as a first spacer structure, and the spacer structure 20 configured to enclose the second sub-pixel 10B is defined as a second spacer structure. A straight line on which the diagonal line of the rhombus in the first direction X extends is defined as a first symmetry line D1, and a straight line on which the diagonal line of the rhombus in the second direction Y extends is defined as a second symmetry line D2. In other words, there is a first symmetry line D1 in each first pixel rows 110, and there is a second symmetry line D2 in each column including the first sub-pixels 10A and the second sub-pixels 10B.

For a first spacer structure and a second spacer structure adjacent to each other along the first direction X, the first side wall 21A of this first spacer structure and the first side wall 21A of this second spacer structure are disposed at opposite sides of the corresponding first symmetry line D1. The corresponding first symmetry line D1 that corresponds to the first spacer structure is the first symmetry line of the first pixel row 110 including the first sub-pixel 10A enclosed by this first spacer structure. The corresponding first symmetry line D1 that corresponds to the second spacer structure is the first symmetry line of the first pixel row 110 including the second sub-pixel 10B enclosed by this second spacer structure. The first side walls 21A adjacent to each other along the first direction X are configured to contact with each other and are electrically connected. By this arrangement manner of the first side walls 21A, the cathodes 13 of the sub-pixels 10 from adjacent first pixel row 110 and second pixel row 120 may be mutually electrically connected through the first side walls 21A, thereby realizing mutual electrical connection between the cathodes 13 of the sub-pixels 10 of the pixel structure, and forming a whole panel connection of the cathodes 13, which is beneficial to the homogeneity of the cathodes 13.

For a first spacer structure and a second spacer structure adjacent to each other along the second direction Y: the first side wall 21A of this first spacer structure and the first side wall 21A of the second spacer structure are disposed at a same side of the corresponding first symmetry lines D1 respectively; or, the first side wall 21A of this first spacer structure and the first side wall 21A of this second spacer structure are disposed on different sides of the corresponding first symmetry lines D1 respectively.

In some embodiments, the first symmetry line D1 includes a first side G1 and a second side G2 disposed opposite to each other along the second direction Y. The first side G1 corresponding to each first symmetry line D1 is disposed at a same side of the second direction Y. For example, as illustrated in FIG. 1, the first side G1 is on a side pointed by the arrow of the second direction Y, or vice versa.

In some embodiments, the first side wall 21A of the first spacer structure and the first side wall 21A of the second spacer structure adjacent to the first spacer structure along the second direction Y are both disposed on a first side G1 of a corresponding first symmetry line D1.

As illustrated in FIG. 1 to FIG. 3, FIG. 3 is a schematic structural diagram of a pixel structure according a second embodiment of the present disclosure.

In some embodiments, as illustrated in FIG. 3, for a first spacer structure and a second spacer structure adjacent to each other along the second direction Y, the first side wall 21A of this first spacer structure is disposed on the second side G2 of the first symmetry line D1 corresponding to the first spacer structure, and the first side wall 21A of this second spacer structure is also disposed on the second side G2 of a first symmetry line D1 corresponding to the second spacer structure.

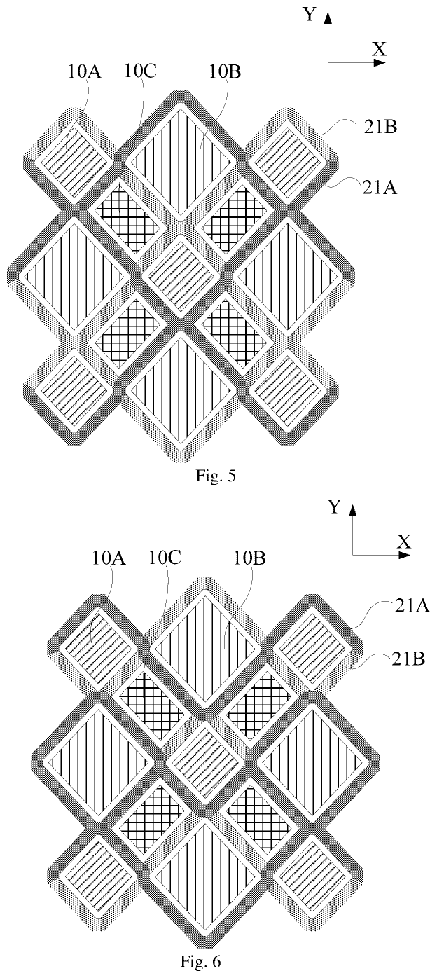

As illustrated in FIG. 1, FIG. 2, FIG. 4 to FIG. 5, FIG. 4 is a schematic structural diagram of a pixel structure according a third embodiment of the present disclosure. FIG. 5 is a schematic structural diagram of a pixel structure according a fourth embodiment of the present disclosure.

In some embodiments, for the first spacer structure and the second spacer structure adjacent to each other along the second direction Y, the first side wall 21A of the first spacer structure and the first side wall 21A of the second spacer structure are disposed on different sides of the corresponding first symmetry lines D1 respectively. In some embodiments, as illustrated in FIG. 4, the first side wall 21A of the first spacer structure is disposed on the first side G1 of the first symmetry line D1 corresponding to the first spacer structure, and the first side wall 21A of the second spacer structure is disposed on the second side G2 of the first symmetry line D1 corresponding to the second spacer structure. In some embodiments, as illustrated in FIG. 5, the first side wall 21A of the first spacer structure is disposed on the second side G2 of the first symmetry line D1 corresponding to the first spacer structure, and the first side wall 21A of the second spacer structure is disposed on the first side G1 of the first symmetry line D1 corresponding to the second spacer structure.

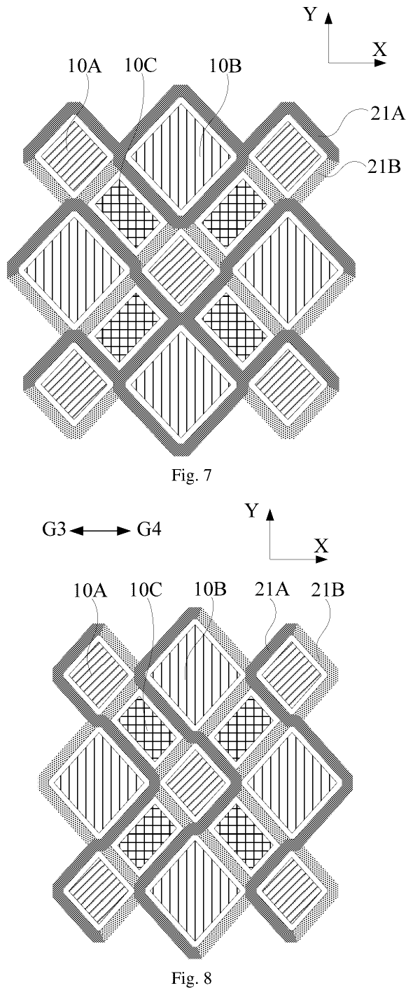

As illustrated in FIG. 1, FIG. 2 and FIG. 6, FIG. 6 is a schematic structural diagram of a pixel structure according a fifth embodiment of the present disclosure.

A structure of the fifth embodiment of the present disclosure is substantially similar to that of the first embodiment. The difference between the fifth embodiment and the first embodiment is that: the side walls 21 of a part of or some the second spacer structures are all first side walls 21A.

In some embodiments, the side walls 21 of a part of the first spacer structures are all first side walls 21A, and/or, the side walls 21 of a part of the second spacer structures are all first side walls 21A. By providing all the side walls 21 of a part of the first spacer structures as the first side wall 21A, the attachment area between the first spacer structure and the cathode 13 of the first sub-pixel 10A enclosed by this first spacer structure may be increased, thereby enhancing the electrical connection effect between this first spacer structure and the cathode 13 of the corresponding first sub-pixel 10A. The attachment area between the first spacer structure and the cathode 13 of the third sub-pixel 10C adjacent to the first spacer structure may also be increased, thereby enhancing the electrical connection effect between the first spacer structure and the cathode 13 of the adjacent third sub-pixel 10C. Similarly, by providing all the side walls 21 of a part of the second spacer structures as the first side wall 21A, an attachment area between the second spacer structure and the cathode 13 of the second sub-pixel 10B enclosed by this second spacer structure may be increased, thereby enhancing the electrical connection effect between this second spacer structure and the cathode 13 of the second sub-pixel 10B. The attachment area between the second spacer structure and the cathode 13 of an third sub-pixel 10C adjacent to the second spacer structure may also be increased, thereby enhancing the electrical connection effect between the second spacer structure and the cathode 13 of the adjacent third sub-pixel 10C.

In the present disclosure, “A and/or B” means only A is included, or only B is included, or both A and B are included.

In some embodiments, the side walls 21 of a part of the second spacer structures are all first side walls 21A. In some embodiments, all the side walls 21 of the second spacer structure corresponding to or enclosing the second sub-pixel 10B in the even-numbered first pixel rows 110 are the first side walls 21A.

As illustrated in FIG. 1, FIG. 2 and FIG. 7, FIG. 7 is a schematic structural diagram of a pixel structure according a sixth embodiment of the present disclosure.

In some embodiments, the side walls 21 of a part of the second spacer structures are all first side walls 21A. In some embodiments, as illustrated in FIG. 6, all the side walls 21 of the second spacer structure corresponding to or enclosing the second sub-pixel 10B in the odd-numbered first pixel rows 110 are the first side walls 21A.

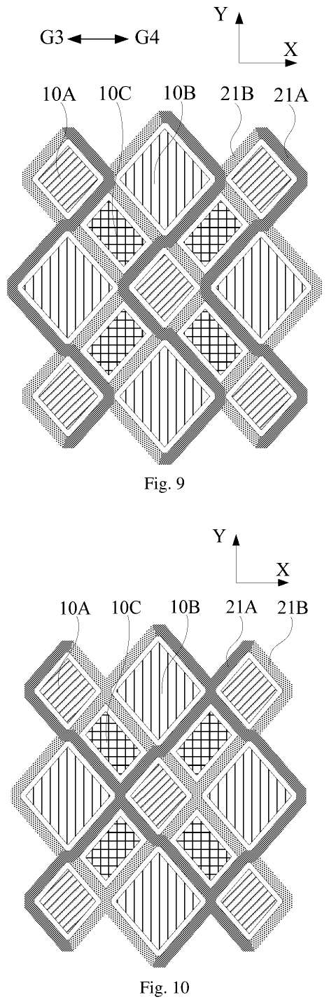

As illustrated in FIG. 1, FIG. 2 and FIG. 8, FIG. 8 is a schematic structural diagram of a pixel structure according a seventh embodiment of the present disclosure.

A structure of the seventh embodiment of the present disclosure is substantially similar to that of the first embodiment. The difference between the seventh embodiment and the first embodiment is that: for a first spacer structure and a second spacer structure adjacent to each other along the second direction Y, the first side wall 21A of this first spacer structure and the first side wall 21A of this second spacer structure are disposed at opposite sides of the corresponding second symmetry line D2. The corresponding second symmetry line D2 that corresponds to the first spacer structure is the second symmetry line D2 of the column including the first sub-pixel 10A enclosed by this first spacer structure, and the corresponding second symmetry line D2 that corresponds to the second spacer structure is the second symmetry line D2 of the column including the second sub-pixel 10B enclosed by this second spacer structure. The first side walls 21A adjacent to each other along the second direction Y are configured to contact each other and are electrically connected.

In some embodiments, for the first spacer structure and the second spacer structure adjacent to each other along the second direction Y, the first side wall 21A of the first spacer structure and the first side wall 21A of the second spacer structure are disposed on two opposite sides of the corresponding second symmetry line D2. The first side walls 21A adjacent to each other along the second direction Y are configured to contact each other and are electrically connected.

In some embodiments, the second symmetry line D2 includes a third side G3 and a fourth side G4 disposed opposite to each other along the first direction X. The third side G3 of each second symmetry line D2 is disposed at a same side of the second direction Y. For example, as illustrated in FIG. 8, the third side G3 is at the left side of the second direction Y.

For the first spacer structure and the second spacer structure adjacent to each other along the first direction X, the first side wall 21A of the first spacer structure and the first side wall 21A of the second spacer structure are disposed at the same side of the corresponding second symmetry lines D2 respectively.

In some embodiments, in an odd-numbered first pixel row 110, the first side wall 21A of the first spacer structure is disposed on the third side G3 of the second symmetry line D2 corresponding to the first spacer structure, and the first side wall 21A of the second spacer structure adjacent to the first spacer structure is also disposed on the third side G3 of the second symmetry line D2 corresponding to the second spacer structure. In an even-numbered first pixel row 110, the first side wall 21A of the first spacer structure is disposed on the fourth side G4 of the second symmetry line D2 corresponding to the first spacer structure, and the first side wall 21A of the second spacer structure adjacent to the first spacer structure is also disposed on the fourth side G4 of the second symmetry line D2 corresponding to the second spacer structure.

As illustrated in FIG. 1, FIG. 2 and FIG. 9, FIG. 9 is a schematic structural diagram of a pixel structure according an eighth embodiment of the present disclosure.

In some embodiments, as illustrated in FIG. 9, in an odd-numbered first pixel row 110, the first side wall 21A of the first spacer structure is disposed on the fourth side G4 of the second symmetry line D2 corresponding to the first spacer structure, and the first side wall 21A of the second spacer structure adjacent to the first spacer structure is also disposed on the fourth side G4 of the second symmetry line D2 corresponding to the second spacer structure. In an even-numbered first pixel row 110, the first side wall 21A of the first spacer structure is disposed on the third side G3 of the second symmetry line D2 corresponding to the first spacer structure, and the first side wall 21A of the second spacer structure adjacent to the first spacer structure is also disposed on the third side G3 of the second symmetry line D2 corresponding to the second spacer structure.

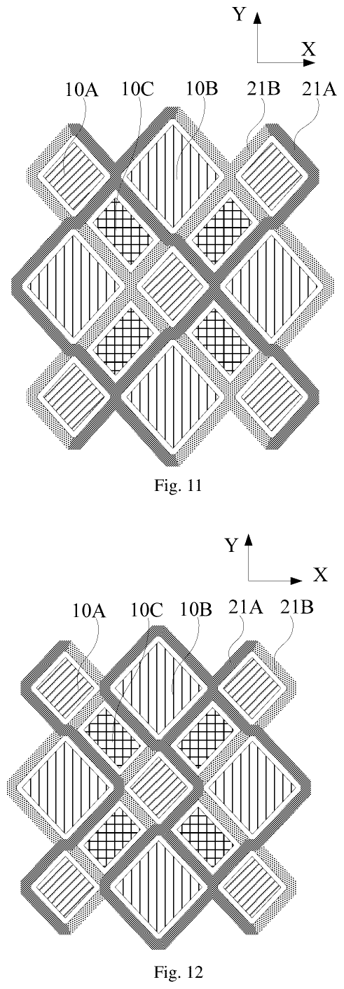

As illustrated in FIG. 1, FIG. 2, FIG. 10 to FIG. 11, FIG. 10 is a schematic structural diagram of a pixel structure according a ninth embodiment of the present disclosure, and FIG. 11 is a schematic structural diagram of a pixel structure according a tenth embodiment of the present disclosure.

In some embodiments, for the first spacer structure and the second spacer structure adjacent to each other along the first direction X, the first side wall 21A of the first spacer structure and the first side wall 21A of the second spacer structure are disposed on different sides of corresponding second symmetry lines D2 respectively. In some embodiments, as illustrated in FIG. 10, the first side wall 21A of the first spacer structure is disposed on the third side G3 of the second symmetry line D2 corresponding to the first spacer structure, and the first side wall 21A of the second spacer structure is disposed on the fourth side G4 of the second symmetry line D2 corresponding to the second spacer structure. In some embodiments, as illustrated in FIG. 11, the first side wall 21A of the first spacer structure is disposed on the fourth side G4 of the second symmetry line D2 corresponding to the first spacer structure, and the first side wall 21A of the second spacer structure is disposed on the third side G3 of the second symmetry line D2 corresponding to the second spacer structure.

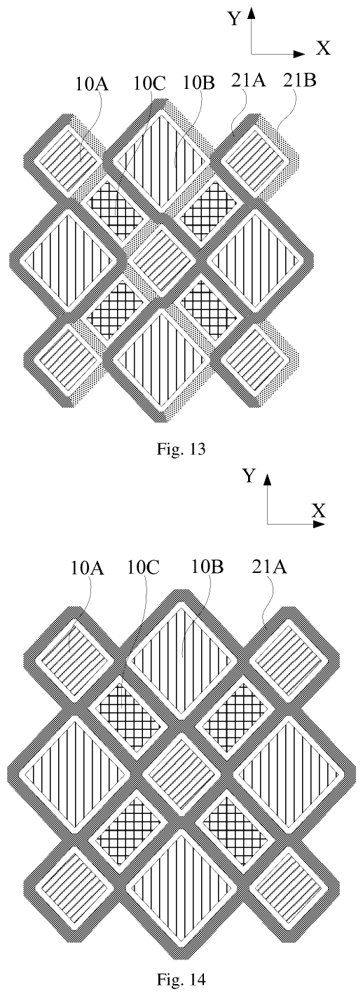

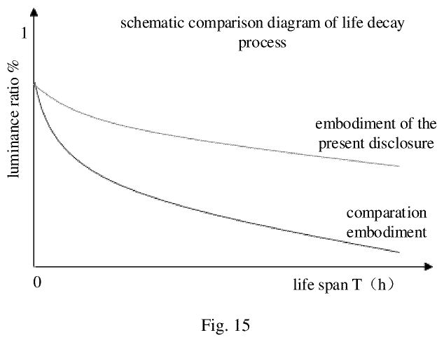

As illustrated in FIG. 1, FIG. 2, FIG. 12 to FIG. 14, FIG. 12 is a schematic structural diagram of a pixel structure according an eleventh embodiment of the present disclosure, FIG. 13 is a schematic structural diagram of a pixel structure according a twelfth embodiment of the present disclosure, and FIG. 14 is a schematic structural diagram of a pixel structure according a thirteenth embodiment of the present disclosure.

In some embodiments, the side walls 21 of a part of the first spacer structures are all first side walls 21A (not illustrated), and/or, the side walls 21 of a part of the second spacer structures are all first side walls 21A, as illustrated in FIG. 12 and FIG. 13. No more will be elaborated here. For more details, please refer to the above-mentioned descriptions.

In some embodiments, as illustrated in FIG. 14, all the side walls 21 of the spacer structure 20 are the first side walls. In comparison with other embodiments of the present disclosure, a better electrical connection between the spacer structure 20 and the sub-pixel 10 may be achieved in this embodiment.

As illustrated in FIG. 1 to FIG. 15, FIG. 15 is a schematic comparison diagram of a sub-pixel life decay process according to an embodiment of the present disclosure.

The above embodiments differ only in the specific arrangement location of the first side walls 21A of the spacer structure 20. In all these embodiments, the area of the pixel aperture 31 may be effectively increased, and the pixel current density may be reduced, thereby effectively enhancing the product lifespan, while further reducing the production cost of the pixel structures. In some embodiments, in comparison with the pixel structure of the related art prepared by an FMM process, the spacing between the sub-pixels 10 of the pixel structure of the present disclosure may be reduced by approximately 10 micrometers. In this way, provided a same pixel layout, the pixel aperture ratio of the pixel structure of the present disclosure may be approximately doubled as compared to the related art. In addition, as illustrated in FIG. 15, the embodiment illustrated in the figure represents an embodiment of the present disclosure, and the comparison embodiment in the figure represents an embodiment of the related art without the spacer structure 20 of the present disclosure. As is illustrated in FIG. 15, in the present disclosure, the lifespan capacity of the pixel structure is significantly improved in the present application as compared to the related art.

A display panel is provided in the present disclosure. The display panel includes any of the above-described pixel structures.

In the above-mentioned embodiments, a description of each embodiment has its own focus, and a part not detailed in a certain embodiment may be referred to relevant descriptions of other embodiments.

The above are only implementations of the present disclosure, and do not limit the patent scope of the present disclosure. Any equivalent changes to the structure or processes made by the description and drawings of this application or directly or indirectly used in other related technical field are included in the protection scope of this application.

What is claimed is:

1. A pixel structure, comprising a first sub-pixel, a second sub-pixel and a third sub-pixel, the colors of the first sub-pixel, the second sub-pixel and the third sub-pixel being different from each other, wherein
the first sub-pixel and the second sub-pixel are alternately disposed along a first direction and form a first pixel row, a plurality of the third sub-pixels are disposed along the first direction and form a second pixel row;
the first pixel row and the second pixel row are alternately disposed along a second direction, the first direction and the second direction are perpendicular to each other;
two first sub-pixels and two second sub-pixels from adjacent two rows and adjacent two columns are arranged in a 2×2 matrix, the two first sub-pixels are located in different rows and different columns, the two second sub-pixels are located in different rows and different columns, two centers of the two first sub-pixels and the two centers of the two second sub-pixels are capable of being connected to form a virtual quadrilateral; the third sub-pixel is located within the virtual quadrilateral; a side of the third sub-pixel is parallel to an proximate side of an adjacent sub-pixel;
the pixel structure further comprises spacer structures, the spacer structures are configured to enclose the sub-pixels, and are in one-to-one correspondence with the sub-pixels; the spacer structures are configured to electrically connect the cathodes of the sub-pixels to each other.

2. The pixel structure as claimed in claim 1, wherein
each of the first sub-pixel and the second sub-pixel is a rhombus, the third sub-pixel is a parallelogram;
a diagonal line of the rhombus is configured to extend in the first direction, another diagonal line of the rhombus is configured to extend in the second direction;
the first sub-pixel and the second sub-pixel adjacent to each other along the first direction are configured to be disposed as corner-facing-corner, and the first sub-pixel and the second sub-pixel adjacent to each other along the second direction are configured to be disposed as corner-facing-corner;
a side of the spacer structure is parallel to a proximate side of a sub-pixel adjacent to the spacer structure;
the first sub-pixel and the third sub-pixel adjacent to the first sub-pixel share a side wall of the spacer structure, and the second sub-pixel and the third sub-pixel adjacent to the second sub-pixel share a side wall of the spacer structure.

3. The pixel structure as claimed in claim 2, wherein
a region enclosed by the spacer structure is polygonal;
corners of the region enclosed by the spacer structure configured to enclose the first sub-pixel are flat chamfers or rounded chamfers, and corners of the region enclosed by the spacer structure configured to enclose the second sub-pixel are flat chamfers or rounded chamfers.

4. The pixel structure as claimed in claim 2, wherein
the spacer structure comprises a spacer part and an eave structure, the eave structure is provided on an upper surface of the spacer part;
the eave structure is configured to cover the spacer part, and extend beyond the spacer part in a direction parallel to the spacer part;
a cross-section of the spacer structure along a plane parallel to the eave structure is configured to taper along a direction toward the eave structure.

5. The pixel structure as claimed in claim 4, wherein
for each spacer structure, at least a part of the side wall is a first side wall;
the spacer part of the first side wall is electrically conductive, and is configured to contact the cathode of the sub-pixel adjacent to the first side wall, and achieve an electrical connection between the spacer structure and the sub-pixel;
the cathode of the sub-pixel is vaporized onto a surface of the light-emitting layer of the sub-pixel by a vaporization source, the first direction is a long-edge direction of the vaporization source, and the second direction is a scanning direction of the vaporization source.

6. The pixel structure as claimed in claim 5, wherein
a part of the side walls of each spacer structure is the first side wall, and another part of the side walls of the each spacer structure is a second side wall; and
the spacer part of the second side wall is insulating.

7. The pixel structure as claimed in claim 5, wherein
the spacer structure configured to enclose the first sub-pixel is referred to as a first spacer structure, and the spacer structure configured to enclose the second sub-pixel is referred to as a second spacer structure;
a straight line on which the diagonal line of the rhombus extending in the first direction configured to extend is referred to as a first symmetry line, and a straight line on which the diagonal line of the rhombus extending in the second direction configured to extend is referred to as a second symmetry line;
for the first spacer structure and the second spacer structure adjacent to each other along the first direction, the first side wall of the first spacer structure and the first side wall of the second spacer structure are disposed at opposite sides of the corresponding first symmetry line; the first side walls adjacent to each other along the first direction are configured to contact each other and are electrically connected;
for the first spacer structure and the second spacer structure adjacent to each other along the second direction:
the first side wall of the first spacer structure and the first side wall of the second spacer structure are disposed at the same side of the respectively corresponding first symmetry lines; or
the first side wall of the first spacer structure and the first side wall of the second spacer structure are disposed at opposite sides of the respectively corresponding first symmetry lines.

8. The pixel structure as claimed in claim 5, wherein
the spacer structure configured to enclose the first sub-pixel is referred to as a first spacer structure, and the spacer structure configured to enclose the second sub-pixel is referred to as a second spacer structure;
a straight line on which the diagonal line of the rhombus extending in the first direction configured to extend is referred to as a first symmetry line, and a straight line on which the diagonal line of the rhombus extending in the second direction configured to extend is referred to as a second symmetry line;
for the first spacer structure and the second spacer structure adjacent to each other along the second direction, the first side wall of the first spacer structure and the first side wall of the second spacer structure are disposed at opposite sides of the corresponding second symmetry line; the first side walls adjacent to each other along the second direction are configured to contact each other and are electrically connected;
for the first spacer structure and the second spacer structure adjacent to each other along the first direction:
the first side wall of the first spacer structure and the first side wall of the second spacer structure are disposed at the same side of the respectively corresponding second symmetry lines; or
the first side wall of the first spacer structure and the first side wall of the second spacer structure are disposed at opposite sides of the respectively corresponding second symmetry lines.

9. The pixel structure as claimed in claim 7, wherein
the side walls of a part of the first spacer structures are all first side walls; and/or
the side walls of a part of the second spacer structures are all first side walls.

10. The pixel structure as claimed in claim 8, wherein
the side walls of a part of the first spacer structures are all first side walls; and/or
the side walls of a part of the second spacer structures are all first side walls.

11. A display panel comprising a pixel structure, wherein
the pixel structure comprises a first sub-pixel, a second sub-pixel and a third sub-pixel, and the colors of the first sub-pixel, the second sub-pixel and the third sub-pixel are different from each other;
the first sub-pixel and the second sub-pixel are alternately disposed along a first direction and form a first pixel row, a plurality of the third sub-pixels are disposed along the first direction and form a second pixel row;
the first pixel row and the second pixel row are alternately disposed along a second direction, the first direction and the second direction are perpendicular to each other;
two first sub-pixels and two second sub-pixels from adjacent two rows and adjacent two columns are arranged in a 2×2 matrix, the two first sub-pixels are located in different rows and different columns, the two second sub-pixels are located in different rows and different columns, two centers of the two first sub-pixels and the two centers of the two second sub-pixels are capable of being connected to form a virtual quadrilateral; the third sub-pixel is located within the virtual quadrilateral; a side of the third sub-pixel is parallel to a proximate side of an adjacent sub-pixels;
the pixel structure further comprises spacer structures, the spacer structures are configured to enclose the sub-pixels, and are in one-to-one correspondence with the sub-pixels; the spacer structures are configured to electrically connect the cathodes of the sub-pixels to each other.

12. The display panel as claimed in claim 11, wherein
each of the first sub-pixel and the second sub-pixel is a rhombus, the third sub-pixel is a parallelogram;
a diagonal line of the rhombus is configured to extend in the first direction, another diagonal line of the rhombus is configured to extend in the second direction;
the first sub-pixel and the second sub-pixel adjacent to each other along the first direction are configured to be disposed as corner-facing-corner, and the first sub-pixel and the second sub-pixel adjacent to each other along the second direction are configured to be disposed as corner-facing-corner;
a side of the spacer structure is parallel to a proximate side of a sub-pixel adjacent to the spacer structure;
the first sub-pixel and the third sub-pixel adjacent to the first sub-pixel share a side wall of the spacer structure, and the second sub-pixel and the third sub-pixel adjacent to the second sub-pixel share a side wall of the spacer structure.

13. The display panel as claimed in claim 12, wherein
a region enclosed by the spacer structure is polygonal;
corners of the region enclosed by the spacer structure configured to enclose the first sub-pixel are flat chamfers or rounded chamfers, and corners of the region enclosed by the spacer structure configured to enclose the second sub-pixel are flat chamfers or rounded chamfers.

14. The display panel as claimed in claim 12, wherein
the spacer structure comprises a spacer part and an eave structure, the eave structure is provided on an upper surface of the spacer part;
the eave structure is configured to cover the spacer part, and extend beyond the spacer part in a direction parallel to the spacer part;
a cross-section of the spacer structure along a plane parallel to the eave structure is configured to taper along a direction toward the eave structure.

15. The display panel as claimed in claim 14, wherein
for each spacer structure, at least a part of the side wall is a first side wall;
the spacer part of the first side wall is electrically conductive, and is configured to contact the cathode of the sub-pixel adjacent to the first side wall, and achieve an electrical connection between the spacer structure and the sub-pixel;
the cathode of the sub-pixel is vaporized onto a surface of the light-emitting layer of the sub-pixel by a vaporization source, the first direction is a long-edge direction of the vaporization source, and the second direction is a scanning direction of the vaporization source.

16. The display panel as claimed in claim 15, wherein
a part of the side walls of each spacer structure is the first side wall, and another part of the side walls of the each spacer structure is a second side wall; and
the spacer part of the second side wall is insulating.

17. The display panel as claimed in claim 15, wherein
the spacer structure configured to enclose the first sub-pixel is referred to as a first spacer structure, and the spacer structure configured to enclose the second sub-pixel is referred to as a second spacer structure;
a straight line on which the diagonal line of the rhombus extending in the first direction configured to extend is referred to as a first symmetry line, and a straight line on which the diagonal line of the rhombus extending in the second direction configured to extend is referred to as a second symmetry line;
for the first spacer structure and the second spacer structure adjacent to each other along the first direction, the first side wall of the first spacer structure and the first side wall of the second spacer structure are disposed at opposite sides of the corresponding first symmetry line; the first side walls adjacent to each other along the first direction are configured to contact each other and are electrically connected;
for the first spacer structure and the second spacer structure adjacent to each other along the second direction:
the first side wall of the first spacer structure and the first side wall of the second spacer structure are disposed at the same side of the respectively corresponding first symmetry lines; or
the first side wall of the first spacer structure and the first side wall of the second spacer structure are disposed at opposite sides of the respectively corresponding first symmetry lines.

18. The display panel as claimed in claim 15, wherein
the spacer structure configured to enclose the first sub-pixel is referred to as a first spacer structure, and the spacer structure configured to enclose the second sub-pixel is referred to as a second spacer structure;
a straight line on which the diagonal line of the rhombus extending in the first direction configured to extend is referred to as a first symmetry line, and a straight line on which the diagonal line of the rhombus extending in the second direction configured to extend is referred to as a second symmetry line;
for the first spacer structure and the second spacer structure adjacent to each other along the second direction, the first side wall of the first spacer structure and the first side wall of the second spacer structure are disposed at opposite sides of the corresponding second symmetry line; the first side walls adjacent to each other along the second direction are configured to contact each other and are electrically connected;
for the first spacer structure and the second spacer structure adjacent to each other along the first direction:
the first side wall of the first spacer structure and the first side wall of the second spacer structure are disposed at the same side of the respectively corresponding second symmetry lines; or
the first side wall of the first spacer structure and the first side wall of the second spacer structure are disposed at opposite sides of the respectively corresponding second symmetry lines.

19. The display panel as claimed in claim 17, wherein
the side walls of a part of the first spacer structures are all first side walls; and/or
the side walls of a part of the second spacer structures are all first side walls.

20. The display panel as claimed in claim 18, wherein
the side walls of a part of the first spacer structures are all first side walls; and/or
the side walls of a part of the second spacer structures are all first side walls.
